(19) United States
(12) Patent Application Publication
(10) Pub. No.: US 2019/0120708 A1
(43) Pub. Date: Apr. 25, 2019

(54) ASSESSING AND MINIMIZING INTEGRATED CIRCUIT (IC) CHIP WARPAGE DURING MANUFACTURING AND USE

(71) Applicant: International Business Machines Corporation, Armonk, NY (US)

(72) Inventors: Chandrasekharan Kothandaraman, New York, NY (US); Shidong Li, Poughkeepsie, NY (US); Katsuyuki Sakuma, Fishkill, NY (US)

(73) Assignee: International Business Machines Corporation, Armonk, NY (US)

(21) Appl. No.: 15/792,906

(22) Filed: Oct. 25, 2017

(51) Int. Cl. G01L 1/16; G01L 1/18; H01L 21/66

(52) U.S. Cl. CPC G01L 1/16; H01L 22/34; G01L 1/18

(57) ABSTRACT

An on-chip strain gage for monitoring strain on an integrated circuit (IC) chip, the IC chip and method of monitoring and mitigating stress induced chip warpage. The strain gage sensor includes a strain sensor element in a single layer. The strain gage sensor quantifies and digitizes local strain which reflects local chip stress from chip warpage. During normal chip usage, the strain information may be used to alter chip operation.

### BACKGROUND

### Field of the Invention

The present invention is related to integrated circuit (IC) chips and particularly to assessing and minimizing warpage in IC chips manufacturing and use.

### Background Description

Generally, Hooke's law provides that the strain or deformation of an elastic object or material is proportional to the stress (force) applied to it. It is well known in the integrated circuit (IC) chip manufacturing arts that heat during chip fabrication, as well as internally generated heat from subsequent environmental conditions, can deform the chip, known as warping. Moreover, during normal IC chip usage both localized heating and heat cycling can easily cause warpage strain as well. Warpage strain causes stress that progressively degrades chip materials during fabrication, and frequently leads to abnormal events and catastrophic failures, especially for yield and reliability. Thus, progressive warpage and strain during fabrication and chip service life are indicators of material degradation and potential catastrophic abnormal events.

Additionally, as IC fabrication technologies progress, back end of the line (BEOL) features shrink to twenty two nanometers (22 nm) and below. These technologies use more porous, low-modulus ultra-low-k materials in BEOL. These ultra-low-k materials cause additional, chip-package-interaction (CPI) susceptibility to warpage strain, making packaging more challenging.

Thus, there is a need for on-chip monitoring warpage strain in real-time and more particularly for monitoring and characterizing warpage strain in real-time, during chip fabrication, packaging and in use, and for taking steps to mitigate stress.

### SUMMARY

A feature of the invention is real-time on-chip warpage monitoring;

Another feature of the invention is a compact strain element for monitoring and characterizing warpage strain in real-time, during chip fabrication, packaging and in use;

Yet another feature of the invention is a single layer, thin film strain sensor and strain gage circuit for real-time monitoring and mitigating stress induced chip warpage during chip fabrication, packaging and in use.

The present invention relates to an on-chip strain gage for monitoring strain on an integrated circuit (IC) chip, the IC chip and method of monitoring and mitigating stress induced chip warpage. The strain gage sensor includes a strain sensor element in a single layer. The strain gage sensor quantifies and digitizes local strain which reflects local chip stress from chip warpage. During normal chip usage, the strain information may be used to alter chip operation.

### BRIEF DESCRIPTION OF THE DRAWINGS

The foregoing and other objects, aspects and advantages will be better understood from the following detailed description of a preferred embodiment of the invention with reference to the drawings, in which:

FIG. 1 shows an example of a preferred strain gage employing a preferred single layer, thin-film strain sensor for measuring warpage in semiconductor integrated circuit (IC) chips

FIG. 2 shows an example of a preferred includes a single, thin-film layer strain sensor element for sensing local strain in strain sensor;

FIG. 3 shows table with examples of selected material gage factors;

FIGS. 4A-B show examples of semiconductor gage factors;

FIG. 5 shows a table with examples of several measureable piezoelectric properties;

FIG. 6 shows an example of a chip with multiple strain gages distributed about an IC chip for monitoring and characterizing strain and warpage in real-time;

FIG. 7 shows a simple example of an IC chip with a preferred strain gage;

FIG. 8 shows an example of a method for using a preferred strain gage for measuring and monitoring strain in a chip.

### DETAILED DESCRIPTION

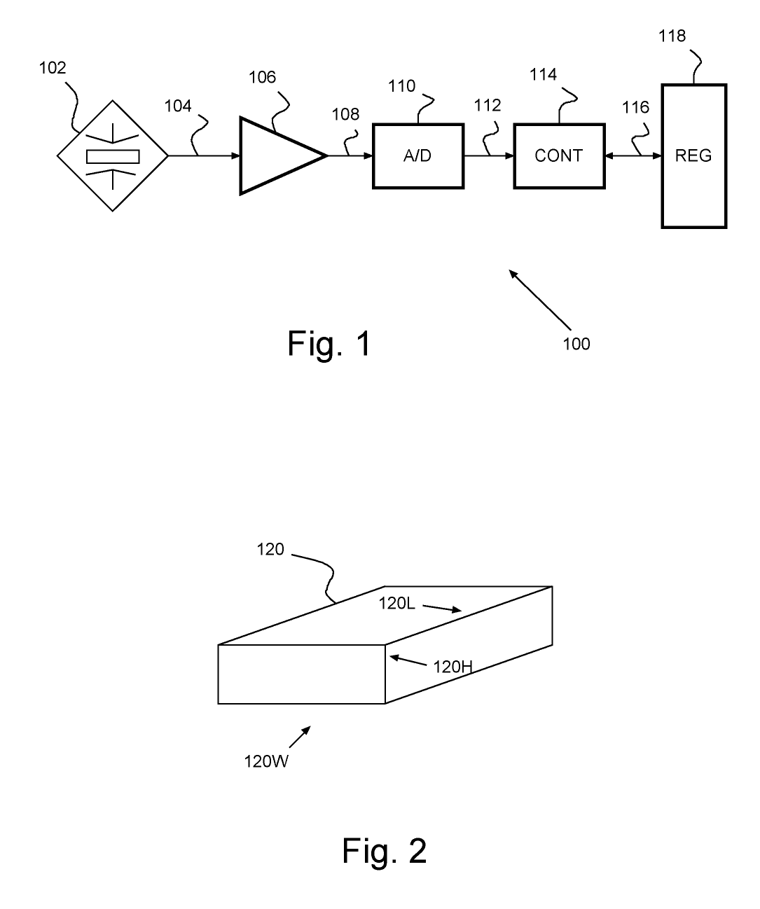

Turning now to the drawings and more particularly FIG. 1 shows an example of a preferred strain gage 100 employing a preferred single layer, thin-film strain sensor 102 for measuring warpage in semiconductor integrated circuit (IC) chips, according to preferred embodiments of the present invention. Preferably, the strain sensor 102 is a stress sensitive material, e.g., a metal, piezoresistive material or piezoelectric material. The strain gage 100 quantifies stress from that strain sensor 102 providing a measure of strain response 104. The quantified stress results provide for measuring strain from warping induced during fabrication, and even occurring during subsequent normal use.

In this example, the preferred strain gage 100 also includes an amplifier 106, e.g., an operational amplifier. The amplifier 106 receives the stress responses 104 and provides an amplified signal 108 to an analog to digital (A/D) converter 110. The A/D converter 110 quantifies the amplified signal as a digital output 112. Also in this example, a suitable microcontroller 114 interrogates the digital output 112 against stored prior history and threshold values, and may store the interrogation results 116 in a register 118 for subsequent application.

FIG. 2 shows an example of a preferred includes a single, thin-film layer strain sensor element 120 for sensing local stress by strain sensor 102. A preferred strain sensor 102 may simply be the strain sensor element 120, alone, or as a resistor in a Wheatstone bridge. The thin-film material may be any suitable metal, semiconductor, piezoresistive or piezoelectric material, a dielectric, or any other material with a property that has a measurable response to stress. Alternatively, the strain sensor element could change its dielectric constant in response to strain and this change can be measured by the changes in the capacitance of a suitably patterned structure. A preferred strain sensor element 120 is a single, thin-film layer element, a rectangular element in this example.

For a piezoresistive thin-film layer element 120, the element 120 has a known, process dependent sheet resistance (ρ) and the strain sensor 120 has length (L) 120L, width (b) 120W, thickness or height (h) 120H and area A=L·W. Thus, the strain sensor element 120 has a nominal resistance determined by: R=ρ·L/A=(ρ/h)·(L/b). It should be noted that piezo-resistive semiconductor is also very sensitive to temperature change. Thus, using a piezoresistive element 120 also provides the optional capability to compensate for temperature through accurately measuring strain.

For a capacitive thin-film layer element 120, the element 120 is a capacitor that has a measurable change in dielectric constant in response to strain. This dielectric constant changes the capacitance of a suitably patterned capacitive element 120.

Local stress originate from strain, force, torque and/or other stimuli caused by the chip warping. Other stimuli may include, for example, displacement, acceleration and/or position. Mechanical strain (ε) contorts the strain element 120 in one or more dimensions 120H, 120L and/or 120W and has the form: ε=ΔD/D, where D is h, L or b depending on how the element 120 contorts. The gage factor (GF) for a strain element 120 is ratio of relative change in electrical resistance (ΔR) to the stress from the mechanical strain and has the form: GF=(ΔR/R)/ε. For any given strain gage, GF is a unit-less constant. It should be noted that GF for a semiconductor strain gauge element, e.g., doped silicon, is 1 to 2 orders magnitude higher than for metal foil strain gauges with the same dimensions.

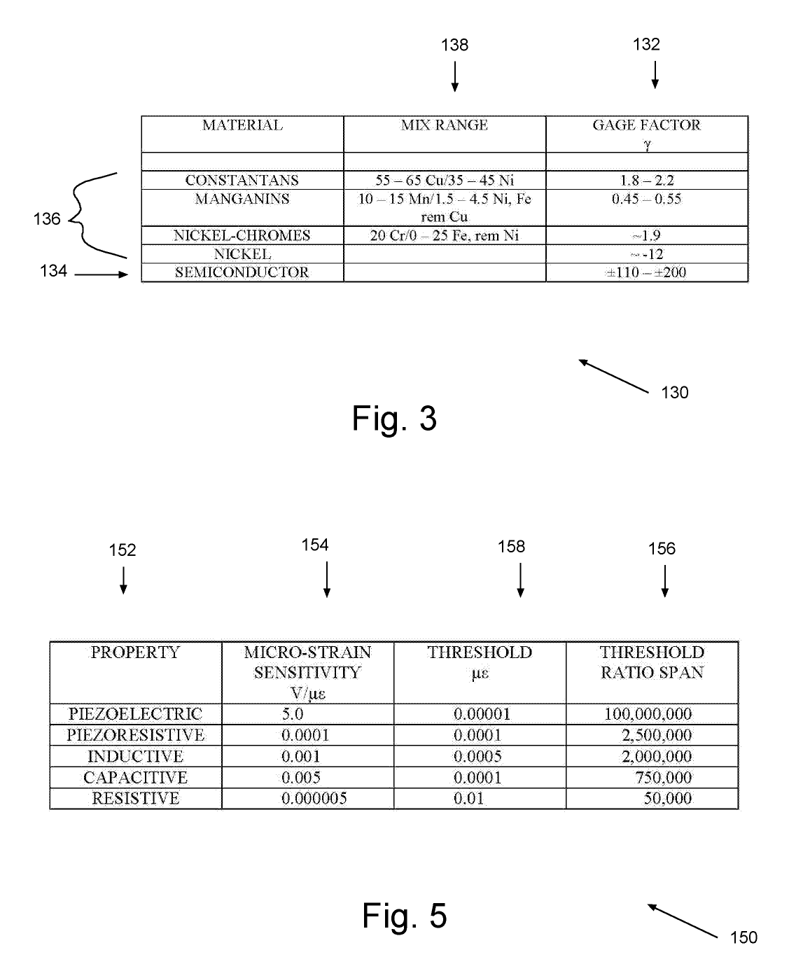

FIG. 3 shows table 130 with examples of gage factors 132 for semiconductor 134, nickels and various metal alloys 136, constantans, manganins and nickel-chromes, with the mix range 138 of metals in each alloy. The type of material used for the element depends on the particular application. Further, for a conductor strain gauge GF is a linear function, while for a semiconductor strain gauge GF is nonlinear.

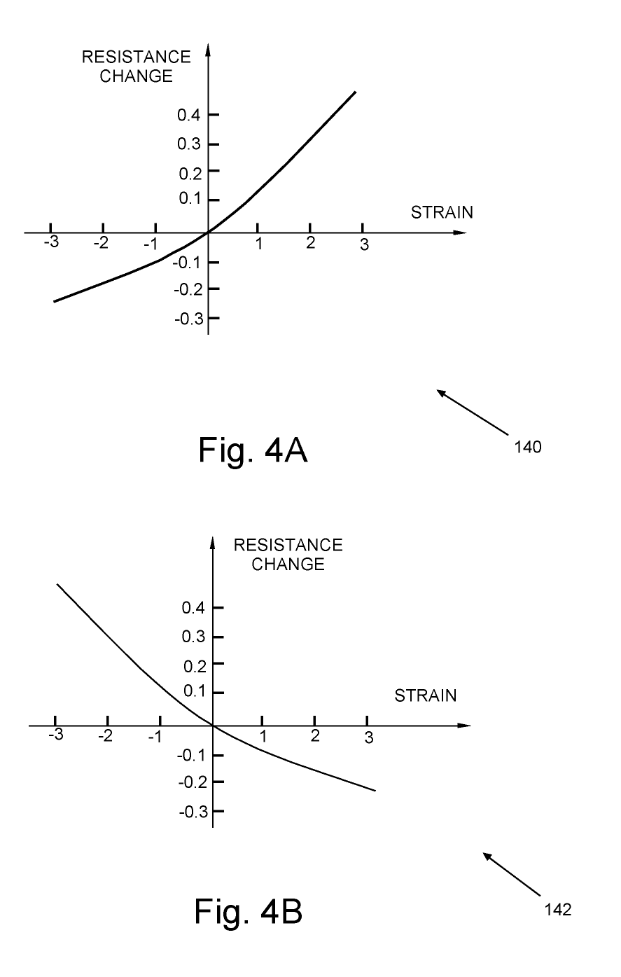

FIGS. 4A-B show examples of semiconductor gage factors 140, 142, which generally have the quadratic form: dR/R=S_{1ε}+S_{1ε}², where S₁ is a stress coefficient for the particular semiconductor. Thus, GF can be determined from the particular material and strain element dimensions. Further, using the element 120 alone as a strain sensor 102 or as a resistor in a Wheatstone bridge, one can derive the gage factor and determine stress in the particular strain sensor 102.

FIG. 5 shows a table 150 with examples of several measureable properties 152 of strain sensitive material. Each property 152 exhibits a corresponding micro-strain (10⁻⁶ε or με) sensitivity 154 (e.g., V/με) along with a threshold (i.e., smallest detectable strain) 156 and a span to threshold ratio or detection range 158.

In one preferred embodiment, the strain sensor element is a semiconductor, e.g., silicon 134 which exhibits the highest gage factor. Further, the selected semiconductor may be piezoresistive material. A piezoresistive semiconductor element may be a doped base material piezoresistor, boron diffusion p-doped, or arsenide diffusion n-doped, doped to a desired base resistance. Piezoresistive strain gauges are much more efficient than simple metal or resistive elements. Piezoresistor element can be compactly utilized in a Wheatstone bridge for accurately measuring resistance changes from strain.

In addition to doped semiconductor, suitable piezoelectric strain sensor material may include, for example, perovskites. Generally, perovskite materials are class of compounds with the same type of crystal structure as calcium titanate (CaTiO₃), i.e., ^{XII}A^{2+VI}B⁴⁺X²⁻₃ A 3 that exhibit dipole moment with strain. A preferred perovskite is lead zirconate titanate (PZT). PZTs are an intermetallic inorganic compound having the form Pb[ZrₓTi₁₋ₓ]O₃, where 0≤x≤1, or (PbZrO₃+PbTiO₃). Other suitable, non-perovskite materials that also show strain sensitivity include, for example, aluminum nitride AlN and zinc oxide ZnO. Advantageously, depositing a thin film of perovskite and defining perovskite elements may be done at any design layer or level, including toward/at the end of chip fabrication, e.g., in the backend of the line (BEOL). For example, a simple mask and deposit or mask and etch step may be used to define a capacitive strain sensor with an easily measured capacitance value at almost any chip layer. Using a BEOL perovskite thin film, for example, is simple and easy, reducing manufacturing cost with minimal yield loss.

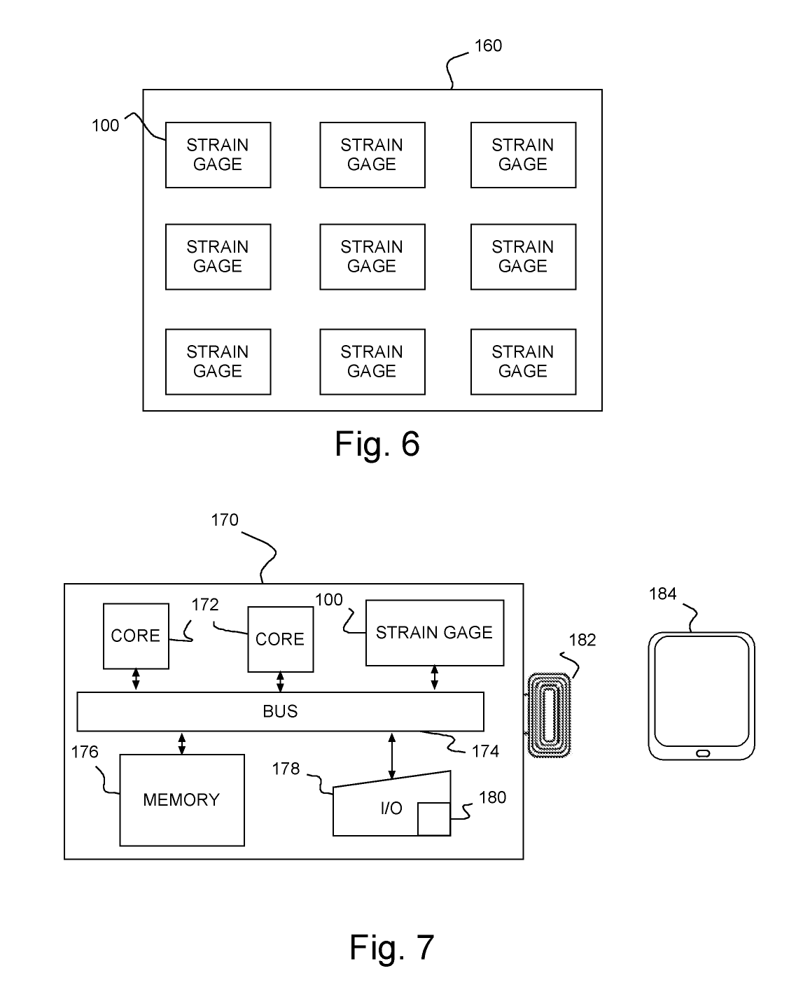

As shown by the example of FIG. 6, a chip 160 may have multiple strain gages, e.g., 100 of FIG. 1, nine (9) in this example, with sensor sensors distributed about the IC chip 160, for monitoring and characterizing strain and warpage in real-time. Further, strain sensor elements for these 9 gages 100 may be formed all at the same fabrication level or distributed at multiple levels for measuring and/or monitoring fabrication strain where strain is known to occur. Optionally, a chip may include strategically located pads for the probing strain gages 100 and measuring strain at the sensors 120 at any fabrication level above wiring connecting devices together to form the strain gage circuit 100. Typically, probe pads are included with bonding pads for normal chip level testing.

Typically, a completed IC chip may be flip-chip bonded to a carrier substrate for high-end applications, or where performance may not be a primary concern wire-bonded to the carrier substrate. With flip-chip bonding the top chip surface (including pads) faces down towards the carrier substrate where the chip is attached, e.g., with the pads soldered to the carrier substrate. Optionally, additional pads may be formed on the back side of the chip, e.g. using through-silicon-vias (TSVs). For a wire-bonded IC chip, extra top-side pads may be provided for probing. These optional pads provide independent strain gage testing, post packaging.

FIG. 7 shows a simple example of an IC chip 170 that includes a preferred strain gage, e.g., 100 of FIG. 1. Multiple processor cores 172, two in this example, connect to each other, and communicate over, a bus 174. The chip bus 174 also couples the cores 172 to on-chip memory 176, chip input/output (I/O) circuits 178 and the strain gage 100. Optionally, chip I/O circuits 178 may include a suitable communications controller, e.g., a Bluetooth or near field communications (NFC) controller. By design the strain gage 100 is physically located on the chip 170 where strain is expected to occur.

Chip warpage that occurs on the chip 170 after forming an element 100. Forming elements early in manufacturing, as well as at subsequent manufacturing layers, provides for characterizing both cumulative and stage by stage process warpage. Further, providing sufficient access to the strain gage 100 during manufacturing provides for in situ monitoring warpage, especially die during chip bonding and assembly. Once the chip 170 is complete through BEOL, the chip 170 itself may measure and digitize fabrication warpage induced strain from the strain gage 100, and optionally, compare the digitized values to a threshold value. Thereafter, during bonding and assembly, differential heating can by controlled and optimized in real-time by monitoring stress and adapting to maintain warpage within desired limits.

Additionally, if the chip I/O circuits 178 include a communications controller 180 such as Bluetooth controller or an NFC controller, the packaged chip may be provided with an antenna (e.g., a Bluetooth or NFC antenna) 182 for communicating with a local external device 184, e.g., a stand-alone computer, smart phone or tablet. An NFC antenna 182, when in the presence of a suitable radio frequency (RF) signal, Bluetooth or NFC, from the external device 184, not only provides for collecting strain data, but also power allows the IC chip 170 NFC controller 180 to extract power from the RF signal. Thus, the IC chip 170 can measure warpage and collect strain information even when the IC chip 170 is disconnected from normal power supplies.

Thus, when used in a suitable field application, the strain gage 100 provides for real-time stress and warpage monitoring even during active chip use. The strain gage 100 may be continually quantifying local strain, or remain dormant until a measurement is desired. Responding to measured strain/stress, the chip or a separate controller in the remote device 184 can take appropriate cooling action, e.g., through core activity modulation, activity rebalancing, or through a specific core process. Also, whenever the measured stress meets or exceeds a threshold, the chip can initiate/alter external cooling to protect itself from warpage-related mechanical stress and reliability problems.

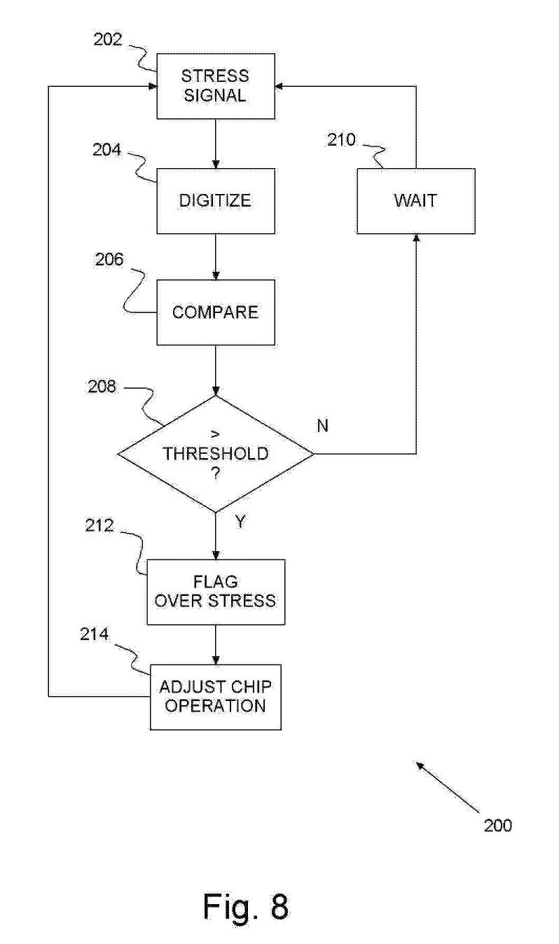

FIG. 8 shows an example of a method 200 of using a preferred strain gage, e.g., 100 in FIG. 1, for measuring and monitoring strain in a chip, e.g., 170 of FIG. 7, and mitigating warpage with a load balancing and/or throttling, according to a preferred embodiment of the present invention. Again, the strain gage 100 may be continually quantifying and amplifying 202 local strain, or remain dormant and periodically measuring. The strain gage 100 digitizes 204 the stress on the sensor 102. Then, the strain gage microcontroller 114 compares 206 the digitized measurement against a threshold, e.g., from the local register 118. If the measured strain is below the threshold 208 then, strain is acceptable and the chip 170 waits 210 until 202 the next scheduled measurement. Optionally, for continuous stress measurement, the chip omits the wait 210 and returns to take the next measurement 202. If, the digitized measurement exceeds the threshold 208; then, the chip 170 can indicate that stress from warpage is beyond the limit 212, and can adjusts 214 core 172 operation to mitigate stress. Once stress is mitigated, the chip 170 returns to take 202 the next scheduled measurement.

Advantageously, a preferred strain gage circuit provides for real-time on-chip warpage monitoring during chip fabrication, packaging and in use. Further, the preferred sensor element is compact, formed in a single selected chip layer. Thus, the preferred strain sensor includes a thin film element that may be formed in any chip layer, as early as in device feature layers to the BEOL. The preferred sensor element, strain sensor and strain gage circuit provide for real-time monitoring and mitigating stress induced chip warpage during chip fabrication, bonding/packaging and in use.

Further, an IC chip with integrated Bluetooth or NFC communications capability and a preferred strain gage circuit can wirelessly provide stress monitoring information over an appropriate wireless network. Moreover, using signals to an NFC antenna, an external device can power the IC chip. Thus, the IC chip can self-measure warpage/die strain even without a normal power supply connection.

While the invention has been described in terms of preferred embodiments, those skilled in the art will recognize that the invention can be practiced with modification within the spirit and scope of the appended claims. It is intended that all such variations and modifications fall within the scope of the appended claims. Examples and drawings are, accordingly, to be regarded as illustrative rather than restrictive.

What is claimed is:

1. An on-chip strain gage for monitoring strain on an integrated circuit (IC) chip comprising:
a strain gage sensor circuit on an IC chip, said IC chip comprising a plurality of layers including a plurality of circuit device layers on a substrate, at least one wiring layer above said plurality of circuit device layers, and at least one chip input/output (I/O) layer at a above one wiring layer; and
a strain sensor element in a single layer of said IC chip, said strain sensor element being connected as an input to said strain gage sensor circuit, said strain gage sensor circuit selectively quantifying strain in said strain sensor element, quantified strain in said strain sensor element to reflect local stress in said IC chip from chip warpage.

2. An on-chip strain gage as in claim 1, wherein said strain sensor element is a piezoelectric or piezoresistive material.

3. An on-chip strain gage as in claim 2, wherein said piezoelectric material is a perovskite.

4. An on-chip strain gage as in claim 3, wherein said perovskite is lead zirconate titanate (PZT).

5. An on-chip strain gage as in claim 2, wherein said strain sensor element is a piezoresistive material selected from the group consisting of semiconductors, metals, metal alloys, constantans, manganins and nickel-chromes.

6. An on-chip strain gage as in claim 5, wherein said piezoresistive material is a doped silicon and said strain sensor element is a doped silicon piezoresistor.

7. An on-chip strain gage as in claim 5, wherein said piezoresistive material is a resistor in a Wheatstone bridge.

8. An integrated circuit (IC) chip comprising:
a substrate;
a plurality of layers including a plurality of circuit device layers on said substrate;
one or more wiring layer above said plurality of circuit device layers;
at least one strain gage sensor circuit, circuit devices in said circuit device layers being connected by wiring in the wiring layers into said strain gage sensor circuit;
at least one chip input/output (I/O) layer at a above one wiring layer; and
at least one strain sensor element in a single layer of said IC chip, said wiring further connecting said at least one strain sensor element as an input to a respective said at least one strain gage sensor circuit, said at least one strain gage sensor circuit selectively quantifying strain in the respective said at least one strain sensor element, quantified strain in said respective at least one strain sensor element to reflect local stress in said IC chip from chip warpage.

9. An IC chip wafer including a plurality of IC chips as in claim 8.

10. An IC chip as in claim 8, wherein said at least one strain gage sensor circuit is a plurality of strain gage sensor circuits monitoring local IC chip stress and said at least one strain sensor element is a plurality of strain sensor elements.

11. An IC chip as in claim 10, wherein said plurality of strain sensor elements is at different locations about said IC chip.

12. An IC chip as in claim 10, wherein said plurality of strain sensor elements are in different layers in said IC chip, said plurality of strain gage sensor circuits further providing for monitoring stress at different manufacturing stages.

13. An IC chip as in claim 12, further comprising a chip packaging attach layer, wherein said IC chip is further attached to and mounted in chip packaging, and wherein said plurality of strain gage sensor circuits further provide for monitoring IC chip stress during normal use.

14. An IC chip as in claim 8, wherein said at least one strain sensor element is a piezoelectric material or piezoresistive material selected from the group consisting of semiconductors, metals, metal alloys, constantans, manganins and nickel-chromes.

15. An IC chip as in claim 14, wherein said piezoelectric material is a perovskite.

16. An IC chip as in claim 14, wherein said piezoresistive material is a doped silicon and said at least one strain sensor element is a doped silicon piezoresistor, and wherein said at least one strain gage sensor circuit comprises:
an amplifier, said doped silicon piezoresistor coupled to an amplifier input;
an analog to digital (A/D) converter quantifying an amplified signal from said amplifier;
a microcontroller interrogating a digital output from said A/D converter; and
a register storing threshold values for comparison by said microcontroller against quantified amplified signal values.

17. An IC chip as in claim 8, further comprising wireless communications controller and a wireless antenna, wherein the IC chip wirelessly provides stress monitoring information to an external device and uses power from electromagnetic energy in signals from said external device to power said at least one strain gage sensor circuit, self-measuring warpage/die strain and wirelessly providing results to said external device.

18. A method of monitoring integrated circuit (IC) chip warpage, said method comprising:
amplifying strain sensor element voltage, said strain sensor element being contained in a single layer of an IC chip;
converting the amplified voltage to a digital value;
comparing said digital value against a threshold value; and whenever said digital value is greater than said threshold value,
modifying chip operation to reduce local stress from chip warpage reflected by said digital value.

19. An method as in claim 18, wherein said strain sensor element is a piezoelectric element and amplifying strain sensor element voltage comprises sensing voltage across said piezoelectric element in an operational amplifier.

20. An method as in claim 18, wherein said strain sensor element is a strain sensitive resistor in a Wheatstone bridge and amplifying strain sensor element voltage comprises sensing voltage across said Wheatstone bridge in an operational amplifier.
